(19) United States
(12) Patent Application Publication
(10) Pub. No.: US 2025/0385162 A1
(43) Pub. Date: Dec. 18, 2025

(54) SEMICONDUCTOR DEVICE ASSEMBLIES WITH WETTABLE DIE ATTACH AREA AND ASSOCIATED METHODS

(71) Applicant: SEMICONDUCTOR COMPONENTS INDUSTRIES, LLC, Scottsdale, AZ (US)

(72) Inventors: Rennier Sarmiento RODRIGUEZ, Calamba City (PH); Allen Mortos MENOR, Calamba City (PH); Philip Jay Banagan DE GUZMAN, General Mariano Alvarez (PH)

(73) Assignee: SEMICONDUCTOR COMPONENTS INDUSTRIES, LLC, Scottsdale, AZ (US)

(21) Appl. No.: 19/231,748

(22) Filed: Jun. 9, 2025

Related U.S. Application Data
(60) Provisional application No. 63/661,419, filed on Jun. 18, 2024.

(51) Int. Cl. H01L 23/495; H01L 21/48; H01L 23/00

(52) U.S. Cl. CPC H01L 23/49513; H01L 21/4835; H01L 24/16; H01L 24/32; H01L 24/73; H01L 2224/16245; H01L 2224/32245; H01L 2224/73204

(57) ABSTRACT

An assembly includes a conductive surface. The conductive surface includes an area with a hydrophilic surface. The hydrophilic surface is prepared by plasma cleaning. A semiconductor die is disposed on the hydrophilic surface. A coupling layer made of an adhesive material bonds the semiconductor die to the hydrophilic surface. The coupling layer fills a gap between the semiconductor die and the hydrophilic surface.

### RELATED APPLICATION

This application claims priority to, and the benefit of, U.S. Provisional Patent Application No. 63/661,419, filed Jun. 18, 2024, which is incorporated by reference in its entirety herein.

### BACKGROUND

Semiconductor device assemblies, such as packages, modules, power modules, and so forth, can include a leadframe, a substrate, and/or other structures to which one or more semiconductor die can be attached. For instance, a leadframe may include at least one die attach area (e.g., a die attach paddle, or a die attach flag) with which one or more semiconductor die can be coupled. A substrate can include a patterned metal layer, which can include one or more surface portions to which one or more semiconductor die can be coupled. For instance, semiconductor die can be coupled to corresponding surface portions using a die attach process, e.g., transferring a semiconductor die from a wafer and then coupling the semiconductor die to a corresponding surface portion, e.g., of a substrate or leadframe, using an adhesive material, such as an epoxy, a resin or a die attach film (DAF).

### SUMMARY

In an aspect, an assembly includes a conductive surface. The conductive surface includes an area with a hydrophilic surface. The hydrophilic surface is prepared by plasma cleaning. A semiconductor die is disposed on the hydrophilic surface. A coupling layer made of an adhesive material bonds the semiconductor die to the hydrophilic surface. The coupling layer fills a gap between the semiconductor die and the hydrophilic surface.

In an aspect, an assembly includes a metal structure including a first portion having a first surface tension, and a second portion having a second surface tension that is less than the first surface tension. A die attach material is disposed on the second portion of the metal structure, and a semiconductor die is disposed on the die attach material.

In an aspect, a method includes forming a mask with a window on a metal surface, cleaning a portion of the metal surface exposed through the window in the mask to define a die attach pad surface, and removing the mask. The method further includes dispensing a die attach adhesive on the die attach pad surface, disposing a semiconductor die on the die attach adhesive on the die attach pad surface, and performing a die attach operation to secure bonding of the semiconductor die to the die attach pad surface.

### BRIEF DESCRIPTION OF THE DRAWINGS

FIG. 1 is a schematic illustration of an example leadframe paddle with a wettable die attach area.

FIG. 2 is a schematic illustration of an example semiconductor device assembly with a semiconductor die disposed on the wettable die attach area of the leadframe paddle of FIG. 1.

FIG. 3 is a cross-sectional view of the semiconductor device assembly of FIG. 2 illustrating the structure of a coupling layer (e.g., an adhesive material layer, a fillet, a slug, a joiner layer, etc.) disposed underneath and on the sidewalls of the semiconductor die that is disposed on the wettable die attach area.

FIG. 4 illustrates an example method for fabricating an example semiconductor device assembly including a semiconductor die disposed on wettable die attach region.

FIGS. 5A to 5G cross-sectional views of a semiconductor die assembly at different stages of construction.

FIG. 6 is a schematic diagram illustrating use of an in-line plasma cleaning tool for plasma cleaning of die attach areas on a leadframe paddle.

FIG. 7 illustrates a cross-sectional view of a portion of the semiconductor device assembly of FIG. 2.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of that element are illustrated.

### DETAILED DESCRIPTION

Die Attach (also known as Die Mount or Die Bond) is the process of attaching or coupling a semiconductor chip (e.g., a semiconductor die) to a die pad or a die cavity of a support structure (e.g., the leadframe) of a semiconductor device package. The semiconductor die may be sourced, for example, by singulating a processed semiconductor wafer attached to a wafer tape. There are two common die attach processes, i.e., adhesive die attach and eutectic die attach. Both of these processes use special die attach equipment and die attach tools to mount the die.

Adhesive die attach uses an adhesive (e.g., a polyimide, an epoxy, or a silver-filled glass, etc.) as a die attach material (a coupling layer) to mount and bond the semiconductor die on the die pad or cavity. The adhesive is first dispensed in controlled amounts on the die pad or cavity to form, for example, a die attach film or coupling layer. The die for mounting is then ejected from the wafer tape by one or more ejector needles.

While being ejected, a pick-and-place tool commonly known as a ‘collet’ then retrieves the die from the wafer tape and positions it on the adhesive of the die attach film or coupling layer. All of the above steps may be done by special die attach equipment or ‘die bonders’. The mass of the adhesive (e.g., epoxy) including adhesive material of the coupling layer (extrusion) climbing up the edges of the die is known as the die attach fillet. An excessive die attach fillet may lead to die attach material contamination of the die surface. Too little of it may lead to die lifting or die cracking.

The die attach material disposed between the die attach pad on the support structure and the semiconductor die can be referred to herein as the adhesive fillet or the coupling layer. Typically, for an underfill coupling layer, gaps between a semiconductor die (or flip-chip) the support structure should be completely filled to provide mechanical reinforcement against harsh thermal and mechanical stresses. In order to achieve this, there is a narrow opening (e.g., window) for the volume or amount of adhesive that can be dispensed to form an ideal coupling layer. A minimum volume or amount of adhesive needed on the die attach pad may be determined based on the absolute minimum coupling layer height and width such that the underfill volume does not lead to an incomplete fill. Similarly, a maximum volume or amount of adhesive that can be tolerated on the die attach pad may be determined such that the coupling layer extrusion does not creep up over the die and end up covering it.

In implementations using an epoxy, or epoxy-like materials, as a die attach adhesive (coupling layer), an adhesive material of the coupling layer can build up on sidewalls of a corresponding semiconductor die during the die attach process. In prior implementations, such coupling layer can exceed a desired height (e.g., a limited percentage of the sidewalls covered by the adhesive), which can then cause molding compound voids in proximity to the coupling layer. Such voids can result in damage to the semiconductor die, such as cracking as a result of thermal cycling. Coupling layers exceeding a desired height can also result in the die attach adhesive migrating onto the upper surface of the corresponding semiconductor die. Die attach adhesive of coupling layer extrusions that has migrated to the upper surface can cause electrical shorts, or cause other problems with the electrical devices, contacts, and circuits fabricated on the upper surface of the die.

In prior implementations, surfaces of leadframes or metal layers of semiconductor die assemblies may be chemically treated with materials to prevent bleed-out of die attach material (e.g., from underneath the semiconductor die). Such bleed-out prevention materials can be referred to as anti-epoxy bleed-out (anti-EBO) materials, and/or anti-resin bleed-out (anti-RBO) materials (all which are collectively referred to hereafter as anti-EBO material). The anti-EBO material may be applied as a hydrophobic film (e.g., which repels water droplets). Such chemical treatment can prevent die attach adhesive material from bleeding into areas where wire bonds are to be formed, as the bled die attach adhesive material can reduce the quality of the wire bonds (e.g., by affecting the formation of wire bond intermetallic between the wire and the leadframe and/or metal layer). However, the anti-EBO material treatment can result in formation of coupling layer extrusions that can exceed a desired height (e.g., 75% of a thickness of a corresponding semiconductor die). In implementations in which the semiconductor die are thinned (e.g., to less than 400 micrometers thick) achieving a coupling layer extrusion or fillet height at or below a desired height (e.g., less than 75% of the die thickness) can be challenging.

Furthermore, such chemical (anti-EBO material) treatment can cause void formation and/or adversely impact adhesion of a die attach film to a corresponding leadframe (die attach paddle or flag) or metal layer. Such voiding and/or reduced adhesion can affect device performance and/or cause reliability issues, such as delamination of semiconductor die from an underlying leadframe (flag or paddle) or metal layer.

The present disclosure describes methods for attaching a semiconductor die on a supporting metal sheet (e.g., a leadframe paddle or flag). The methods involve physiochemical pre-treatment of a portion of a surface of the metal sheet to prepare a die attach area for attaching the semiconductor die. The physiochemical pre-treatment may render the surface of the die attach area to be a hydrophilic surface or, in other words, a wettable surface. The physiochemical pre-treatment can result in the die attach area having a wettable surface area, i.e., a surface area having a low surface tension characteristics. A die attach adhesive layer may be dispensed on, and spread over, the wettable surface area before placement of the semiconductor die on the die attach area. The wettable surface characteristics of the die attach area may prevent or suppress bleed-out of the die attach adhesive layer and also limit formation of coupling layer extrusions or die attach adhesive fillets above a desired height.

In the example methods described herein, a wettable area (or wettable region) is formed on a leadframe (paddle or flag) or a metal layer. In example implementations, the wettable area has a reduced-surface tension (e.g., as compared to a greater surface tension of an anti-EBO material treated region). The surface of the leadframe (paddle or flag) may initially be coated with anti-EBO material. The physicochemical treatment is applied to a portion of the surface to define the die attach area. The physicochemical treatment may clear the anti-EBO material, other coating materials or contamination on the die attach area and form a wettable surface of the die attach area. The physicochemical treatment may include plasma cleaning (etching) of the die attach area.

A semiconductor die is attached to the wettable region, using a die attach epoxy, or a die attach film, etc. The specific operations used in the die attach process may depend on the particular implementation. For instance, the die attach process can include a cure (e.g., bake) operation (e.g., for epoxy and/or resin die attach materials, and/or die attach film material), a pressure-less sintering operation for epoxy and/or resin die attach adhesive materials.

The reduced-surface tension of the wettable region allows for wetting (e.g., spreading, flowing, etc.) of an epoxy (or resin) die attach material on the wettable region, which can reduce die attach material build up on sidewalls of a corresponding semiconductor die and, as a result, reduce the height of any resulting coupling layer extrusions (e.g., as compared to the coupling layer extrusions for a non-wettable surface or anti-EBO surface). Regions of a die attach paddle, a die attach flag, a metal layer, etc. outside the wettable region may be coated with the anti-EBO material. These regions may retain the anti-EBO material treated properties and prevent or limit bleeding (flowing) of the die attach material outside the wettable region (e.g., to areas where wire bonds are to be formed). This limiting feature may allow reducing the thickness (e.g., densification) of semiconductor die, such as to a thicknesses of 200 μm or less).

In implementations using die attach films, the wettable region can improve adhesion of the die attach film (e.g., as compared to a surface of the wettable region treated with anti-EBO material prior to formation of a wettable region). Accordingly, void formation in the die attach film attachment can be reduced, and adhesion can be improved.

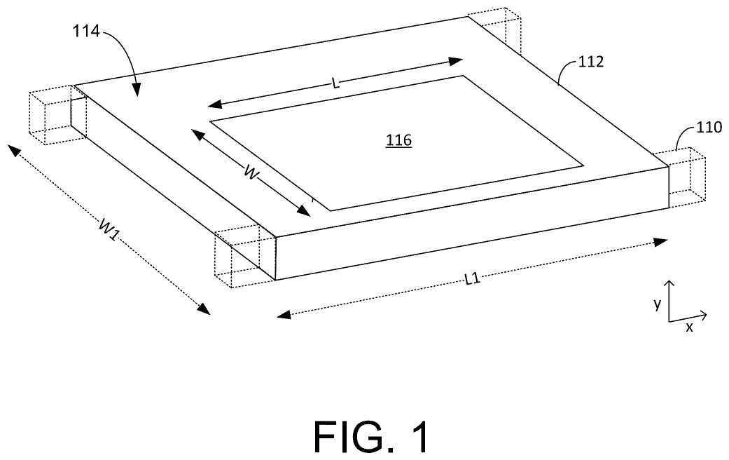

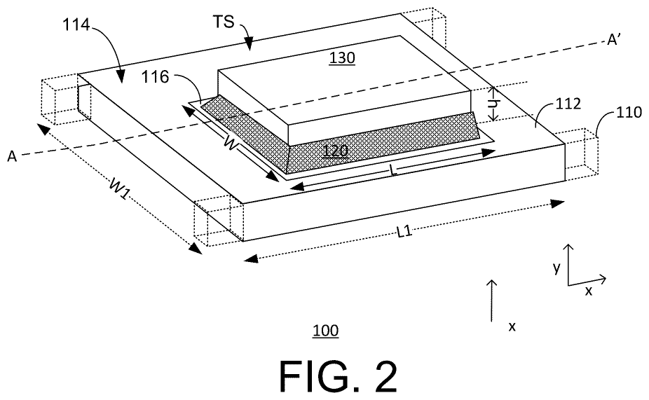

FIG. 1 schematically shows an example leadframe 110 including a paddle or flag on which a semiconductor die can be coupled. For visual clarity, FIG. 1 shows only a leadframe flag or paddle (e.g., paddle 112) portion of leadframe 110. Other portions of the leadframe (e.g., external terminals, support bars, struts) are merely indicated in FIG. 1 by the dashed rectangular boxes at the four corners of paddle 112. Leadframe 110 including paddle 112 may be made of metal (e.g., copper, aluminum, or a metal alloy). In some implementations, portions of leadframe 110 (e.g., paddle 112) may be gold, nickel, palladium, and/or silver plated. Paddle 112 may have L1 and width W1 and a planar top metal surface (e.g., surface TS). A portion of the top metal surface may be configured to serve as a die attach area or pad (e.g., die attach pad 116) to which a semiconductor die (semiconductor die 130, FIG. 2) can be attached using an adhesive layer (adhesive layer 120, FIG. 2). Die attach pad 116 may, for example, have a length L1 and width W1). Portions of surface TS of paddle 112 outside the surface S of die attach pad 116 may be covered by an anti-EBO material 114. Surface S of die attach pad 116 may be physiochemically pretreated to make it a wettable surface. In example implementations, plasma etching or cleaning may be used to pretreat surface S. In example implementations, the plasma etching or cleaning involve the removal of impurities and contaminants from surface S through the use of an energetic plasma created from gaseous species. Gases such as argon or oxygen may be used. The impurities and contaminants removed from surface S may include anti-EBO material 114 that may have spilled over from a previous application of anti-EBO material 114 to surface TS of paddle 112. The plasma cleaning may render the surface S of die attach pad 116 to be wettable i.e., have a low surface tension. The surface tension of surface S will be, for example, less than a surface tension of the anti-EBO portion of surface TS. Adhesive (e.g., adhesive layer 120, FIG. 2) applied to the wettable surface may flow easily and uniformly across surface S. These characteristics of the wettable surface may enable control of a volume of adhesive dispensed to make a good bond with a semiconductor die disposed on surface S. The volume of adhesive dispensed may be controlled so that neither an incomplete fill nor an excess amount of adhesive is applied, since both defects are detrimental for a bond joint. In the case of an incomplete fill, it may not provide enough structural support to the semiconductor die. If there is an excess amount of adhesive, it may cause the adhesive to creep up to the top of the semiconductor die.

FIG. 2 schematically illustrates an example semiconductor die assembly 100 including a semiconductor die 130 disposed on a wettable surface (e.g., die attach pad 116) of a leadframe flag/paddle or patterned metal layer (e.g., leadframe 110 with die attach pad 116, FIG. 1). For purposes of illustration, the leadframe flag/paddle or patterned metal layer may be referred to as a metal structure. In some example implementations, semiconductor die 130 may be oriented on the metal structure such that the active areas (or contacts to the active areas) of the die are facing upward. In some other example implementations, semiconductor die 130 may be oriented on the metal structure such that the active areas of the die are facing downward (e.g., with the die in a flip-chip orientation).

In example implementations, a flag/paddle can be included in a leadframe, such as a copper leadframe, though leadframes including other materials can be used. In some implementations, a patterned metal layer can be included in a first electrically conductive layer of a substrate, such as a direct-bonded metal (DBM) substrate. In some implementations, a DBM substrate can be a direct-bonded copper (DBC) substrate. In an example implementation, the metal structure of FIG. 2 can be a patterned electrically conductive layer (or portion of a patterned electrically conductive layer) that is disposed on a dielectric layer (e.g., ceramic, elastomeric, organic, phenolic, PCB/FR4, etc.). The first electrically conductive layer can include electrically conductive traces of the semiconductor device assembly. In some implementations, a substrate (e.g., a DBM substrate or DBC substrate) can also include a second electrically conductive layer, which can be on an opposite side of the dielectric layer from the first electrically conductive layer. In example implementations, a heat sink, or other thermal dissipation mechanism, can be coupled with second electrically conductive layer.

As shown in FIG. 2, the metal structure includes a portion of a top surface (e.g., surface TS) chemically treated with anti-EBO/anti-RBO chemicals (e.g., anti-EBO material 114). The anti-EBO material 114 may prevent or diminish bleeding of die attach material (e.g., epoxy or resin materials) onto surface TS and preserve or maintain a suitability of surface TS for wire bonding. The chemical treatment with the anti-EBO portion can increase a surface tension the treated portion of surface TS of the metal structure. In the example shown, a wettable surface area (e.g., die attach pad 116) is defined in a portion of surface TS of the metal structure. The wettable surface area may be surrounded by the anti-EBO treated portion. The wettable surface area (e.g., die attach pad 116) may be configured for attachment of one or more semiconductor die (e.g., as a wettable portion within the anti-EBO treated portion). In this example, a surface tension of the wettable surface area is less than the surface tension of the anti-EBO portion.

In the example shown in FIG. 2, a die attach adhesive layer (e.g., adhesive layer 120, an epoxy, resin die attach film) is disposed on the wettable area (e.g., on die attach pad 116), and a semiconductor die 130 is disposed on the die attach adhesive layer. As described herein, physiochemical pre-treatment (e.g., plasma cleaning) of the wettable area (die attach pad 116) reduces the surface tension of the wettable area (as compared to a surface tension of the anti-EBO treated portion). The reduced surface tension allows for complete wetting of the metal structure by the die attach adhesive layer (within the wettable area) and/or improved adhesion of the die attach adhesive layer with the metal structure and with the semiconductor die (in the wettable area). Depending the particular die attach adhesive used, the semiconductor die can be coupled (e.g., bonded) to the metal structure via the die attach adhesive with a curing (e.g., baking) operation, sintering, and/or a pressure-less sintering operation, etc.

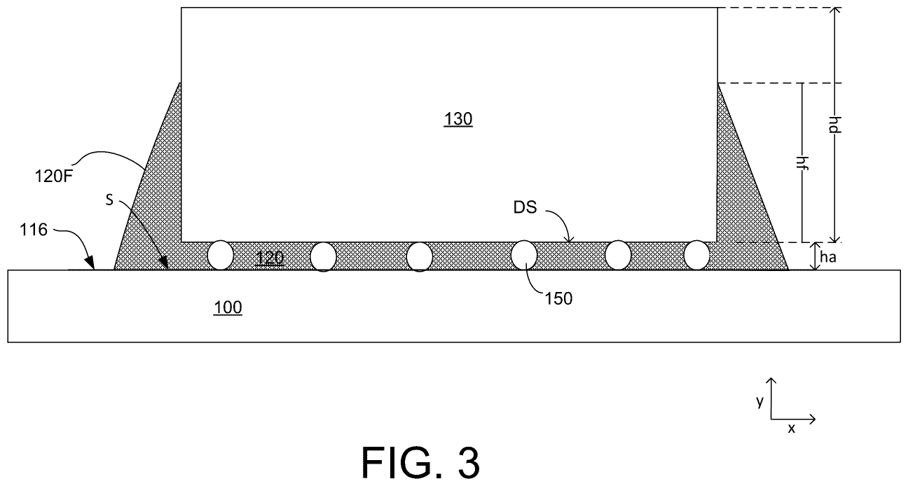

FIG. 3 is a cross-sectional view of a portion of semiconductor die assembly 100 taken along line A-A′ in FIG. 2. FIG. 3 illustrates an example coupling layer 120F in the semiconductor device assembly. In the example shown, semiconductor die 130 may have a thickness of height hd, and may be positioned on the wettable surface area (e.g., on surface S) of die attach pad 116 in a flip-chip orientation with a plurality of solder balls (e.g., solder ball 150) disposed on a bottom side (the downward facing side) of the die for electrical contact to the active areas of the die. The assembly shown in FIG. 3 can be a side view of the assembly of FIG. 2. Coupling layer 120F may include an adhesive layer (e.g., adhesive layer 120 of thickness ha) that completely fills all gaps between the bottom surface of the die (surface DS), the solder balls (e.g., solder ball 150), and the wettable surface (e.g., surface S of die attach pad 116). Further, coupling layer 120F may include some of the adhesive material that has extruded from underneath the die and climbed up the sidewalls of the die to a height hf (e.g., above the die surface DS). In example implementations, height hf may controlled to be less than 75% of the height hd of the die. Height hf may be controlled by limiting the amount adhesive material dispensed on the wettable surface (e.g., surface S) to make an adhesive layer 120 (e.g., void-free adhesive layer) and for securely attaching (bonding) the die to leadframe 110.

As shown in the FIG. 3, the coupling layer 120F can have a height (e.g., on the sidewalls of the semiconductor die) that is less than a thickness of the semiconductor die. As described herein, in some implementations, it is desirable that the coupling layer height is less than or equal to 75% of the thickness of the semiconductor die (or in other words, less than 75% of height of a sidewall of the semiconductor die). For instance, for a semiconductor die with a thickness of 200 μm, the coupling layer height can be 150 μm or less.

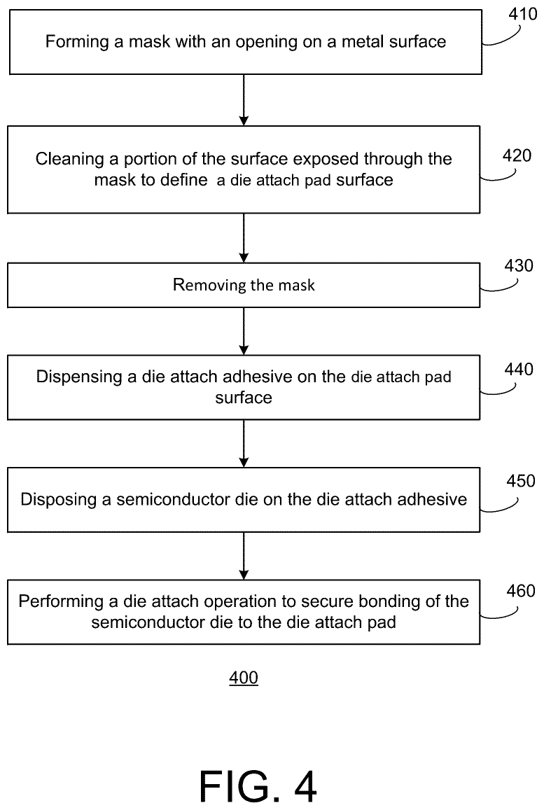

FIG. 4 illustrates an example method 400 for fabricating an example semiconductor device assembly including a semiconductor die disposed on a wettable die attach area of a leadframe. In some example implementations, a surface of a paddle or a flag in a starting leadframe used in method 400 may be initially treated (i.e., coated) with anti-EBO material or solution.

Method 400 includes forming a mask with an opening (e.g., window) on a metal surface (block 410), physiochemically cleaning a portion of the surface exposed through the mask to define a die attach pad surface (block 420), and removing the mask (4 block 30). The metal surface may be a surface of a paddle, a flag, or another structure in a leadframe.

Method 400 further includes dispensing a die attach adhesive on the die attach pad surface (block 440), disposing a semiconductor die on the die attach adhesive (block 450), and performing a die attach operation to secure bonding of the semiconductor die to the die attach pad (block 460). The die attach operation may include curing, baking, sintering, and/or pressure-less sintering operation.

In some example implementations, method 400 may include, prior to forming the mask (block 410) pre-treating the surface of the paddle in the leadframe with an anti-epoxy bleed-out material or solution.

Cleaning (e.g., physiochemically cleaning, plasma cleaning) a portion of the surface exposed through the mask (block 420) may result a die attach pad surface that has a low surface tension and is a wettable surface. The surface tension of the die attach pad surface after plasma cleaning may be lower than a surface tension of the surface of the paddle in the leadframe treated with the anti-epoxy bleed-out material or solution.

Disposing a semiconductor die on the die attach adhesive may include forming a coupling layer made of an adhesive material that fills a gap between the semiconductor die and the die attach pad surface. The coupling layer made of the adhesive material can extend up on an outside sidewall of the semiconductor die to no more than 75% of a thickness of the semiconductor die.

In example implementations, the leadframe used in method 400 may be made of copper, aluminum, other metal, or a metal-alloy. In some example instances, portions of the leadframe may be gold, silver, platinum, palladium, or nickel plated.

In example implementations, the mask may be made of photoresist material, forming the mask may involve photolithography, and removing the mask may involve a photoresist stripping operation.

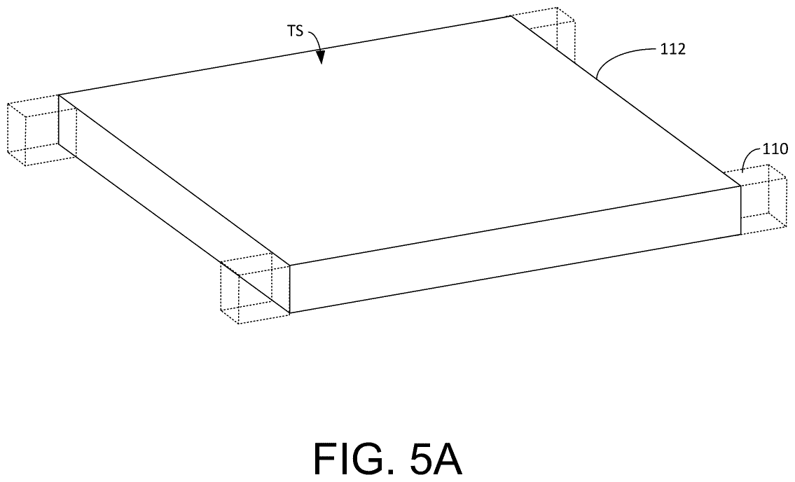

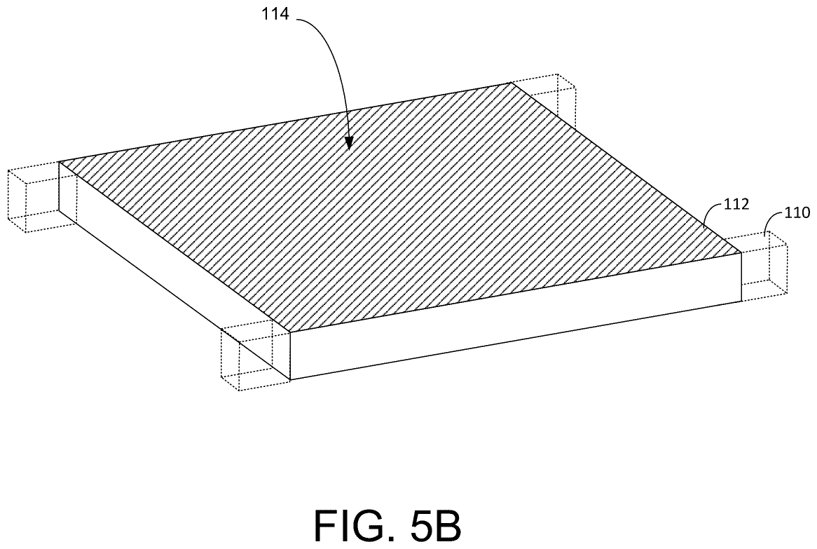

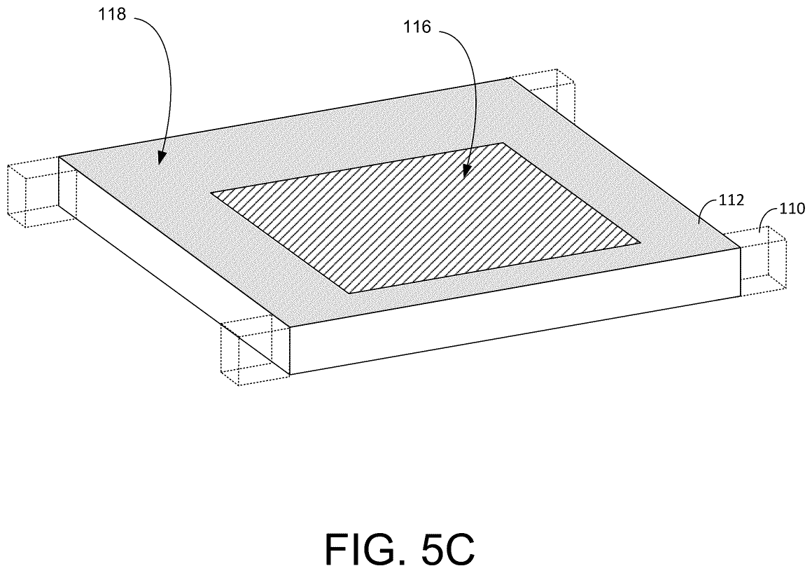

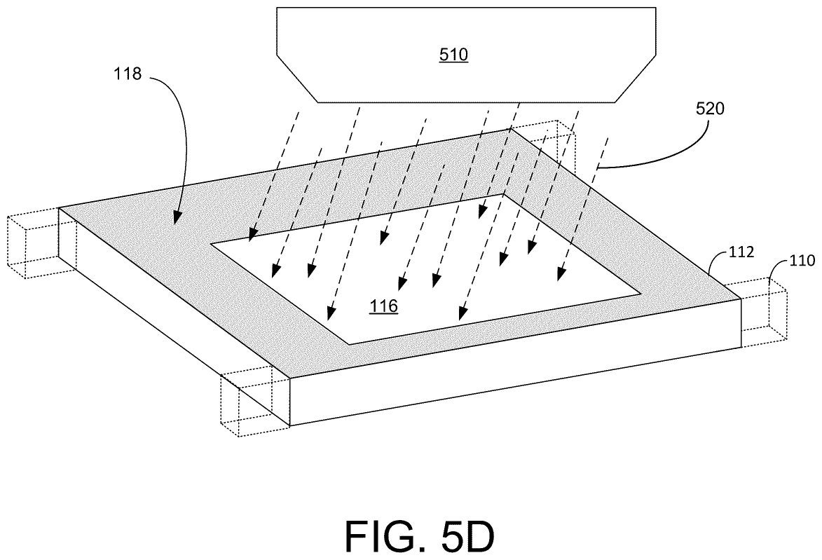

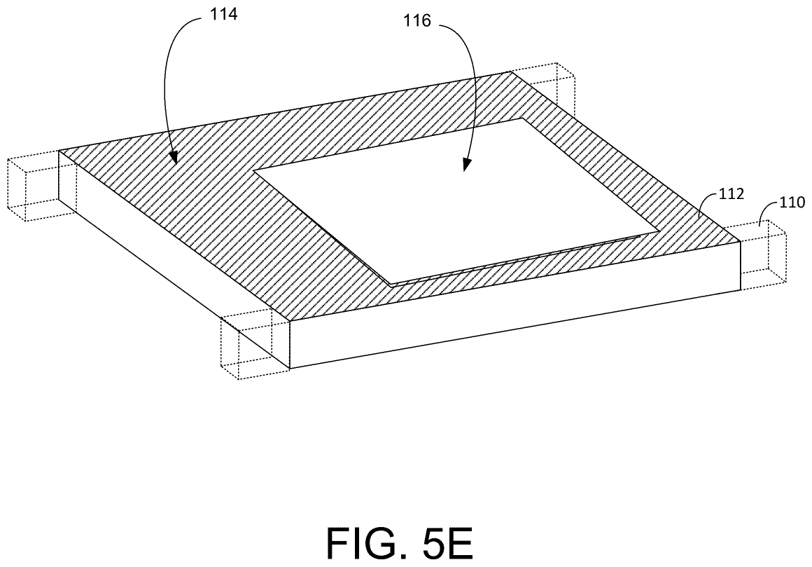

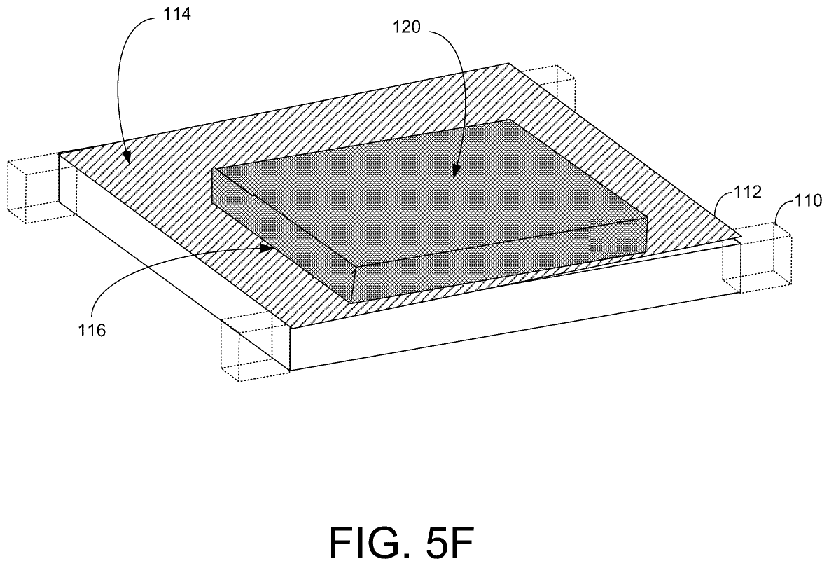

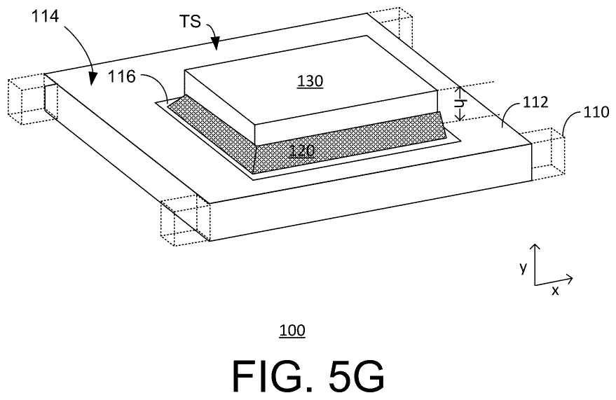

FIGS. 5A to 5F shows schematic cross-sectional views of a semiconductor die assembly at different stages of construction according to, for example, method 400.

The semiconductor die assembly shown in FIGS. 5A to 5F may, for example, correspond to the semiconductor die assembly 100 (shown in FIG. 2) in which a semiconductor die is disposed on a physiochemically pre-treated die attach pad prepared on a metal structure (e.g., on a plate, or flag, or other metal surface of a leadframe). As shown in FIG. 5A, a leadframe 110 has a metal structure (flag, paddle, or metal layer) (e.g., paddle 112) for attachment of a semiconductor die. Paddle 112 can have a metal surface (e.g., upper surface TS). As shown in FIG. 5B, some or all of the upper surface TS of paddle 112 is completely covered with a layer of an anti-EBO material (e.g., anti-EBO material 114).

Next, as shown in FIG. 5C, a mask (e.g., mask 118) can be formed on the upper surface of the metal structure, such that a portion of the anti-EBO material treated surface is exposed through a window (corresponding to an area of die attach pad 116) in the mask. In some implementations, the mask, which may be made of photoresist material, can be formed using a photolithography process. Next, as shown in FIG. 5D, a physiochemical cleaning operation is performed to clean the anti-EBO material treated surface exposed through the mask to form a wettable surface area corresponding to the area of die attach pad 116. In example implementations, the cleaning operation may include a plasma clean and/or plasma etching operation. FIG. 5D shows, for example, a plasma generator head 510, which generates a plasma 520 that is used for cleaning the area of die attach pad 116. In FIG. 5D, for convenience, plasma 520 is depicted as arrows directed to the surface of die attach pad 116. However, in example implementations, plasma 520 may be an isotropic plasma (e.g., a non-directional cloud of ionized gaseous species). In example implementations, plasma 520 may be a stripping plasma (e.g., argon and hydrogen plasma, or an oxygen plasma). The physiochemical cleaning (e.g., plasma cleaning) of the surface of die attach pad 116 may remove all contaminants from the surface and lower a surface tension of the surface of die attach pad 116 (in other words, make of the surface of die attach pad 116 a wettable surface). A surface tension of the wettable surface may be lower than a surface tension of other surfaces of the metal structure including surfaces that are chemically treated with the anti-EBO material. As shown in FIG. 5E, after defining the wettable area (e.g., die attach pad 116), the mask (e.g., mask 118) is then removed from the metal structure. A semiconductor die (or multiple semiconductor die) can then be attached to the wettable area, e.g., using the approaches described herein.

FIG. 5F shows, a metal surface with a controlled amount of an adhesive (adhesive layer 120) disposed on the wettable surface (e.g., die attach pad 116). The adhesive remains on the wettable surface and does not bleed-out on surface adjoining the wettable surface area. The surface adjoining the wettable surface area may be treated with the anti-EBO material 114, but need not be so treated.

Next, as shown in FIG. 5G, a semiconductor die (e.g., semiconductor die 130) is placed on the adhesive layer disposed the wettable surface. Further, curing or baking operations (not shown) may bond the semiconductor die securely to the metal structure and result, for example, in the semiconductor die assembly 100 (FIG. 2).

In example implementations, a die attach operation to couple the semiconductor die with the wettable area can include a cure operation, sintering operation, or a pressure-less sinter operation, etc.

In some implementations, the example process of FIGS. 5A to 5G can be used to produce a semiconductor device assembly having a hybrid-die configuration. For instance, a first die including a first semiconductor material (e.g., silicon) can be coupled with a leadframe or substrate using the processes illustrated in FIGS. 5A to 5G, and a second die including a second semiconductor material (e.g., silicon carbide) can be coupled with the same leadframe or substrate using the processes illustrated in FIGS. 5A to 5G. In some implementations, the processes illustrated in FIGS. 5A to 5G, can be performed concurrently for multiple semiconductor die. In other implementations, the processes es illustrated in FIGS. 5A to 5G, or at least portions of the processes, can be performed sequentially for multiple semiconductor die.

The semiconductor device assemblies described herein may be fabricated in an manufacturing assembly line. The assembly line may be fully automated or may be partially automated. The assembly line may include tools for implementing, for example, method 400 steps including the steps to prepare wettable die attach areas on a leadframe before disposing semiconductor die thereon. The assembly line tools may, for example, include a plasma generation unit, a mask stepper tool, and a conveyor belt for transporting a leadframe through the assembly line.

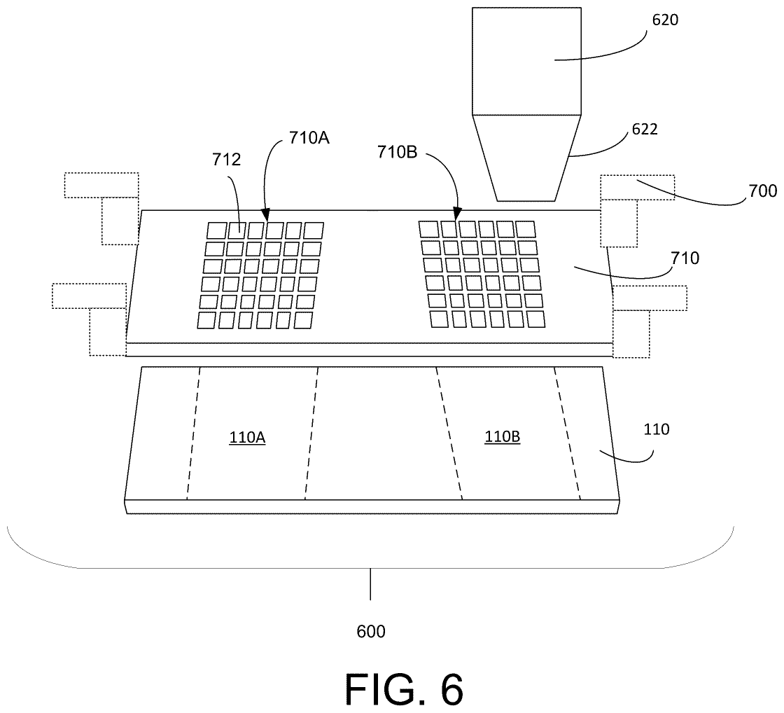

FIG. 6 is a schematic diagram illustrating some of the assembly line tools that are used for the plasma cleaning of die attach areas on a leadframe paddle. In FIG. 6, the plasma generation unit is not explicitly shown but is represented by a plasma gun 620 with a nozzle 622. FIG. 6 shows, for example, a leadframe 110 being transported or pulled through a workstation 600, for example, on a conveyor belt (not shown). Leadframe 110 may be supplied in a reel-form with more than one leadframe (e.g., leadframe 110A and 110B) being exposed in workstation 600 at a given time. A mask-stepper tool 700 may place a mask 710 above leadframe 110 in workstation 600. Mask 710 may include arrays (e.g., array 710A and array 710B) of openings 712 exposing die attach areas (not shown) in leadframe 110A and 110B. The plasma generating unit (plasma gun 620 and nozzle 622) may direct plasma through the openings (e.g., opening 712) in mask 710 to clean the die attach areas in leadframe 110A and 110B.

A result of the foregoing method for precleaning the die attach area prior to semiconductor die attachment is to reduce the height (and width) of the adhesive joiner needed to securely bond the semiconductor die to the die attach area. A further consequence of this result may be that, in example implementations, a landing clearance around a semiconductor die disposed on the leadframe may be decreased. A landing clearance in the context of a semiconductor die refers to the space or gap required between the die and the surrounding die, or the die and the edge of the leadframe, to facilitate wafer expansion, die picking, die bonding, and other processing steps. It is essentially the distance between the die and the edge of the leadframe to prevent contact or damage during handling and processing. The landing clearance ensures that there is sufficient space between the die and other parts or elements during various stages of the semiconductor die manufacturing and assembly process. For example, the landing area outside the landing clearance may be used to receive, for example, one end of a wire bond made between the leadframe and a bond pad on the semiconductor pad.

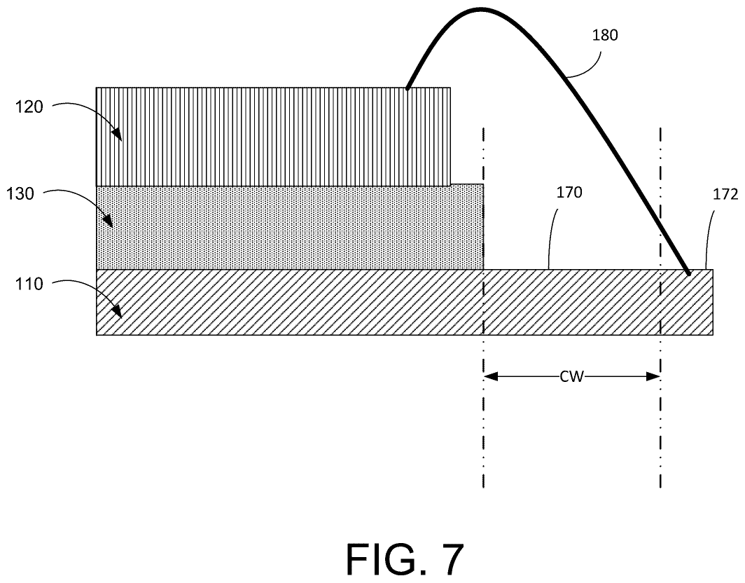

FIG. 7 is a cross-sectional view of a portion of a semiconductor die assembly (e.g., assembly 200, FIG. 2) including a semiconductor die 130 bonded on a precleaned die attach pad of a leadframe 110 by an adhesive layer 120 (e.g., joiner). A limited amount of material may be used for adhesive layer 120 (e.g., joiner) because it is applied to the wettable surface of the die attach pad 116 (FIG. 2). FIG. 7 shows a landing area 172, and a landing clearance 170 (having a width CW) next to an edge of adhesive layer 120 (e.g., joiner) on the surface of leadframe 110. A wire bond 180 can be made between landing area 172 and a bond pad (not shown) on a top surface of the die. Wire bond 180 may be freely made without geometric interference by the semiconductor die. because landing area 172 is outside the landing clearance 170. In example implementations, using method 400 compared to traditional die attach processes, a minimum landing clearance required can be reduced from 13 mils to 11 mils (18%) for small die size and 25 mils to 11 mils (227%) for larger die size.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, a direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer or a coupling material can be an epoxy, a silicone adhesive, a conductive material, a non-conductive material, an organic material, a semiconductor material, a metal alloy, a metal foam, a phase change material, etc.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth. Some implementations may be implemented using various types of semiconductor assemblies, such as assemblies include substrates including, but not limited to, direct-bonded metal (DBM) substrates.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An assembly, comprising:
a conductive surface including an area with a hydrophilic surface;
a semiconductor die disposed on the hydrophilic surface; and
a coupling layer made of an adhesive material bonding the semiconductor die to the hydrophilic surface, wherein the coupling layer fills a gap between the semiconductor die and the hydrophilic surface.

2. The assembly of claim 1,
wherein the semiconductor die disposed on the area in a flip-chip orientation with a plurality of solder balls attached to a bottom side of the semiconductor die, and wherein the coupling layer fills gaps between the semiconductor die, the plurality of solder balls, and the hydrophilic surface.

3. The assembly of claim 1, wherein the semiconductor die has a sidewall with a height, and wherein the coupling layer extends up an outside of the sidewall to no more than 75% of the height.

4. The assembly of claim 1, wherein the area is physiochemically treated prior to disposing the coupling layer and the semiconductor die on the area.

5. The assembly of claim 1, wherein the area is plasma cleaned prior to disposing the coupling layer and the semiconductor die on the area.

6. The assembly of claim 1, wherein a portion of the conductive surface outside the area is treated with an anti-epoxy bleed-out solution.

7. The assembly of claim 6, wherein the portion of the conductive surface outside the area has a surface tension that is greater than a surface tension of a surface of the area.

8. The assembly of claim 1, wherein the conductive surface is a surface of one of:
a die attach paddle of a leadframe;
a die attach flag of a leadframe; or
a metal layer of a direct-bonded metal substrate.

9. An assembly, comprising:
a metal structure including a first portion having a first surface tension, and a second portion having a second surface tension that is less than the first surface tension;
die attach material disposed on the second portion of the metal structure; and
a semiconductor die disposed on the die attach material.

10. The assembly of claim 9, wherein the metal structure is one of:
a die attach paddle of a leadframe;
a die attach flag of a leadframe; or
a metal layer of a direct-bonded metal substrate.

11. The assembly of claim 9, wherein the first portion of the metal structure is chemically treated with an epoxy bleed-out prevention material.

12. The assembly of claim 9, wherein the die attach material is one of:
an epoxy; or
a die attach film.

13. The assembly of claim 9, wherein the die attach material fills a gap between the semiconductor die and the second portion of the metal structure.

14. The assembly of claim 9, wherein the die attach material disposed on the second portion of the metal structure extends up an outside of a sidewall of the semiconductor die to no more than 75% of a height of the sidewall.

15. A method, comprising:
forming a mask with a window on a metal surface;
cleaning a portion of the metal surface exposed through the window in the mask to define a die attach pad surface;
removing the mask;
dispensing a die attach adhesive on the die attach pad surface;
disposing a semiconductor die on the die attach adhesive on the die attach pad surface; and
performing a die attach operation to secure bonding of the semiconductor die to the die attach pad surface.

16. The method of claim 15, wherein the metal surface is a surface of a paddle or a flag in a leadframe.

17. The method of claim 16 further comprising: prior to forming the mask, pre-treating the surface of the paddle or flag with an anti-epoxy bleed-out compound before forming the mask.

18. The method of claim 15, wherein cleaning includes plasma cleaning the portion of the metal surface exposed through the window in the mask.

19. The method of claim 15, wherein disposing a semiconductor die on the die attach adhesive includes forming a coupling layer that fills a gap between the semiconductor die and the die attach pad surface.

20. The method of claim 19, wherein the coupling layer extends up on an outside sidewall of the semiconductor die to no more than 75% of a thickness of the semiconductor die.
